(19) United States
(12) Patent Application Publication
(10) Pub. No.: US 2017/0358557 A1
(43) Pub. Date: Dec. 14, 2017

(54) PACKAGE-ON-PACKAGE STRUCTURE AND MANUFACTURING METHOD THEREOF

(71) Applicant: Powertech Technology Inc., Hsinchu County (TW)

(72) Inventors: Yu-Wei Chen, Hsinchu County (TW); Chi-An Wang, Hsinchu County (TW); Hung-Hsin Hsu, Hsinchu County (TW)

(73) Assignee: Powertech Technology Inc., Hsinchu County (TW)

(21) Appl. No.: 15/434,071

(22) Filed: Feb. 16, 2017

(30) Foreign Application Priority Data
Jun. 8, 2016 (TW) 105118189

(51) Int. Cl. H01L 25/065; H01L 23/00; H01L 23/31; H01L 23/04; H01L 25/00

(52) U.S. Cl. CPC H01L 25/0657; H01L 23/04; H01L 25/50; H01L 23/3114; H01L 24/43; H01L 24/11; H01L 24/16; H01L 2924/1811

(57) ABSTRACT

A POP structure includes a first package structure, an interposer, and a second package structure. The first package structure includes a first carrier, a first chip, conductive structures, and a first insulation encapsulation. The first carrier has a first surface and a second surface opposite to the first surface. The first chip and the conductive structures are disposed on the first surface of the first carrier. The first insulation encapsulation is formed on the first surface of the first carrier and encapsulates the conductive structures and the first chip. Top surfaces of the conductive structures are exposed through the first insulation encapsulation and are coplanar. The interposer is disposed on and electrically connected to the first package structure. The second package structure is disposed on and electrically connected to the interposer. A manufacturing method of a POP structure is also provided.

### CROSS REFERENCE TO RELATED APPLICATION

This application claims the priority benefit of Taiwan application serial no. 105118189, filed on Jun. 8, 2016. The entirety of the above-mentioned patent application is hereby incorporated by reference herein and made a part of specification.

### BACKGROUND OF THE INVENTION

### 1. Field of the Invention

The present invention generally relates to a Package-On-Package (POP) structure and a manufacturing method thereof, and more particularly, to a POP structure having a plurality of fine pitch conductive structures embedded in an insulation encapsulation.

### 2. Description of Related Art

In order for electronic product design to achieve being light, slim, short, and small, semiconductor packaging technology has kept progressing, in attempt to develop products that are smaller in volume, lighter in weight, higher in integration, and more competitive in market. For example, 3D stacking technologies such as POP (Package-On-Package) have been developed to meet the requirements of higher packaging densities. The POP may be formed by, for example, stacking at least two package structures with each other.

The manufacturing method of a package structure of the POP usually includes the step of performing a laser drilling process on the insulation encapsulation to expose the conductive structures. However, the sidewalls of the cavities exposing the conductive structures formed by laser drilling are usually slanted. The slanted sidewalls result in a larger pitch between conductive traces of the package structure. Therefore, fine pitch cannot be achieved in package structure fabricated by the foregoing method. As such, how to achieve fine pitch in the package structure of POP has become a challenge to researchers in the field.

### SUMMARY OF THE INVENTION

The invention provides a POP structure and a manufacturing method thereof, which allows fine pitch arrangement of the conductive traces within the POP structure to be achieved.

The invention provides a POP structure including a first package structure, an interposer, and a second package structure. The first package structure includes a first carrier, a first chip, a plurality of conductive structures, and a first insulation encapsulation. The first carrier has a first surface and a second surface opposite to the first surface. The first chip is disposed on the first surface of the first carrier. The conductive structures are disposed on the first surface of the first carrier. The first insulation encapsulation is formed on the first surface of the first carrier and encapsulates the conductive structures and the first chip. Top surfaces of the conductive structures are exposed through the first insulation encapsulation and are coplanar. The interposer is disposed on and electrically connected to the first package structure. The second package structure is disposed on and electrically connected to the interposer.

The invention provides a manufacturing method of a POP structure. The method includes at least the following steps. A first package structure is formed. The first package structure is formed by the following steps. A first carrier having a first surface and a second surface opposite to the first surface is provided. A plurality of conductive structures are formed on the first surface of the first carrier. A first chip is formed on the first surface of the first carrier. A first insulation encapsulation is formed on the first surface of the first carrier to encapsulate the conductive structures and the first chip. The first insulation encapsulation is grinded until top surfaces of the conductive structures are exposed. Subsequently, an interposer is formed on the first package structure and the interposer is electrically connected to the first package structure. Thereafter, a second package structure is formed on the interposer and the second package structure is electrically connected to the interposer.

Based on the above, the manufacturing method and the shape of the conductive structures in the first package structure allow fine pitch arrangement of the conductive traces to be achieved. In other words, the interposer stacked over the first package structure may include fine pitch interposer conductive terminals. As such, the risk of bridging between the interposer conductive terminals presented in the laser-drilling type manufacturing method is prevented and more conductive traces may be fitted within a specific area. Moreover, since the first insulation encapsulation may be grinded to expose the top surface of the first chip, the cooling efficiency of the first chip may be further increased, thereby enhancing the performance of the POP structure.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1G are schematic cross-sectional views illustrating manufacturing method of a POP structure according to an embodiment of the invention.

FIG. 2A to FIG. 2G are schematic cross-sectional views illustrating manufacturing method of a POP structure according to another embodiment of the invention.

FIG. 3A to FIG. 3G are schematic cross-sectional views illustrating manufacturing method of a POP structure according to yet another embodiment of the invention.

FIG. 4A to FIG. 4C are schematic cross-sectional views illustrating POP structures according to other embodiments of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

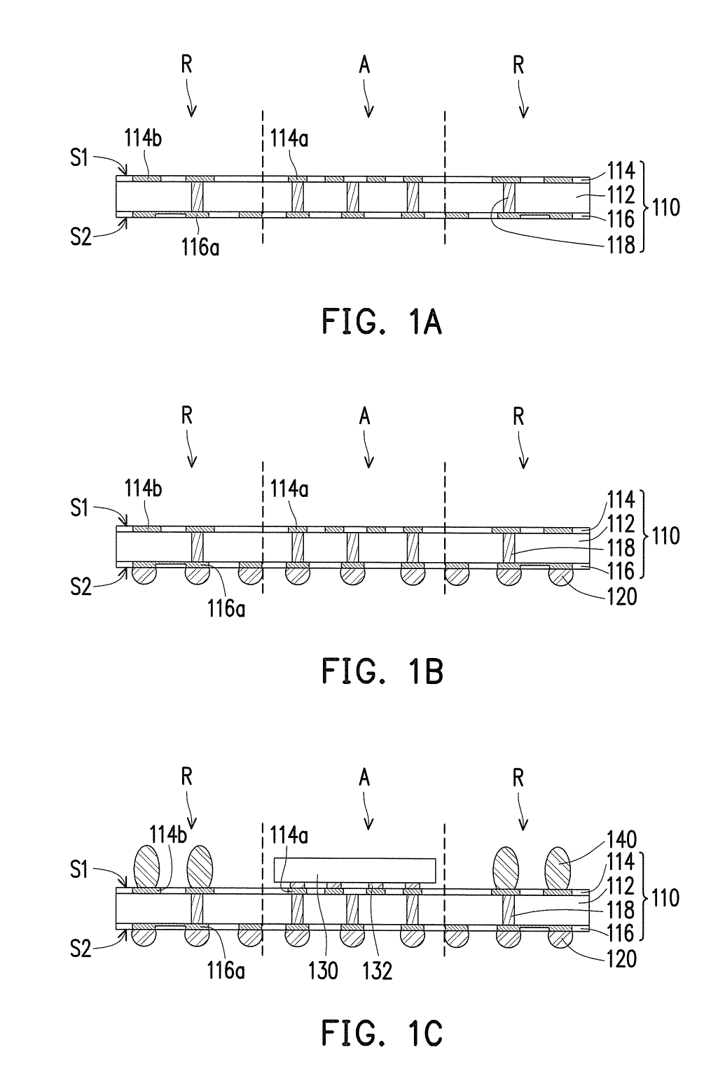

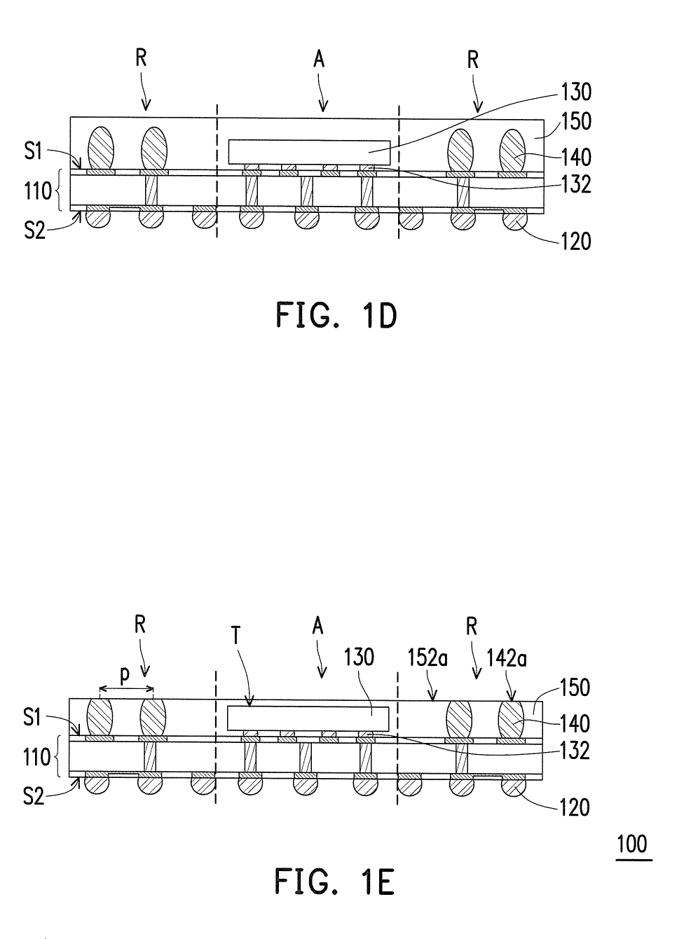

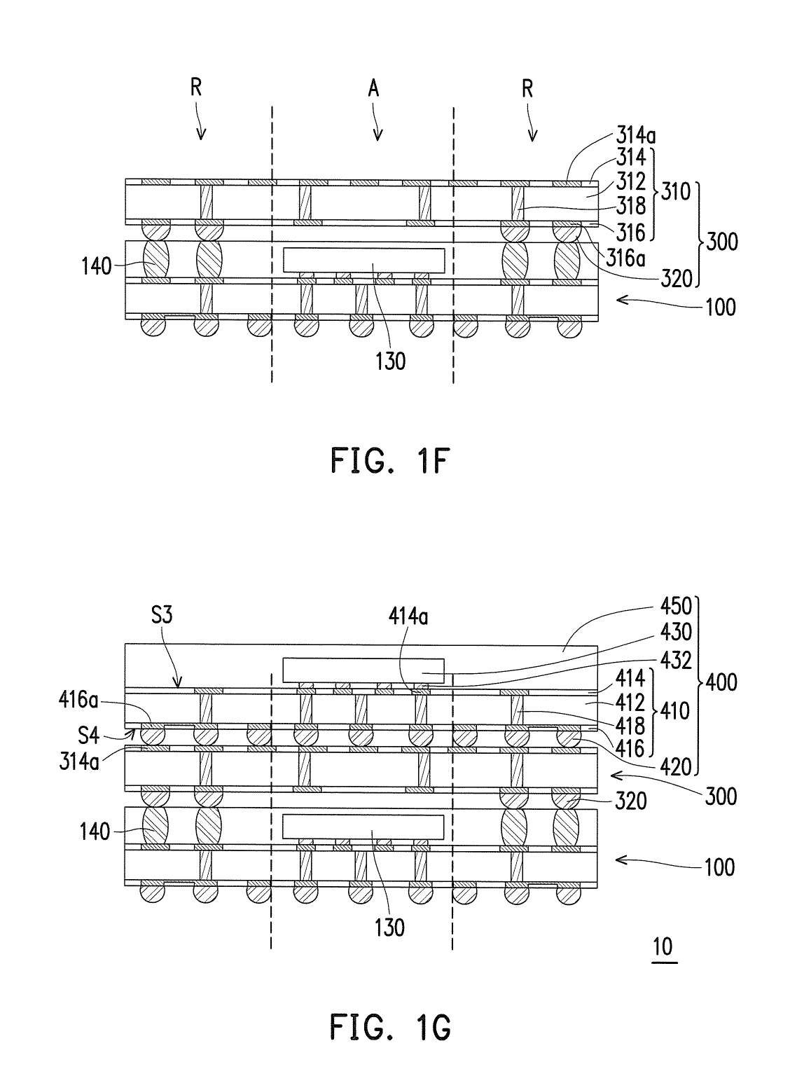

FIG. 1A to FIG. 1G are schematic cross-sectional views illustrating manufacturing method of a POP structure 10 according to an embodiment of the invention. Referring to FIG. 1A, a first carrier 110 is provided. The first carrier 110 has a first surface S1 and a second surface S2 opposite to the first surface S1. The first carrier 110 includes a core layer 112, a first circuit layer 114, a second circuit layer 116, and a plurality of conductive vias 118. The core layer 112 is an intermediate layer of the first carrier 110 and a material of the core layer 112 includes, but is not limited to, glass, epoxy, polyimide (PI), bismaleimide trazine (BT), FR4, or other suitable materials. The first circuit layer 114 and the second circuit layer 116 are formed on two opposite surfaces of the core layer 112, so as to respectively constitute the first surface S1 and the second surface S2 of the first carrier 110. The first carrier 110 is divided into an active region A and a peripheral region R. The peripheral region R surrounds the active region A. In some embodiments, the first circuit layer 114 includes a plurality of conductive pads 114a located in the active region A and a plurality of conductive pads 114b located in the peripheral region R. The second circuit layer 116 includes a plurality of conductive pads 116a. The conductive pads 114a, 114b, and 116a may be formed using copper, solder, gold, nickel, or the like. In addition, the conductive pads 114a, 114b, and 116a may be fabricated by photolithography and etching processes. However, the material and the fabrication method of the conductive pads 114a, 114b, and 116a are not limited thereto, and other suitable material and methods may also be adopted. Each of the conductive vias 118 penetrates through the core layer 112 so the conductive pads 114a and the conductive pads 114b are respectively electrically connected to the conductive pads 116. Some circuit layers in the first carrier 110 are omitted in the illustration presented in FIG. 1A for simplicity. However, in some alternative embodiments, other than the first circuit layer 114 and the second circuit layer 116, the first carrier 110 may also include additional circuit layers embedded in the core layer 112 based on the circuit design.

Referring to FIG. 1B, a plurality of first conductive terminals 120 are formed on the second surface S2 of the first carrier 110. The first conductive terminals 120 are electrically connected to the second circuit layer 116 of the first carrier 110. The first conductive terminals 120 may be disposed corresponding to the conductive pads 116a to render electrical connection between the first conductive terminals 120, the second circuit layer 116, the conductive vias 118, and the first circuit layer 114. In some embodiments, the first conductive terminals 120 are conductive bumps such as solder balls. However, it construes no limitation in the invention. Other possible forms and shapes of the first conductive terminals 120 may be utilized. For example, the first conductive terminals 120 may take the form of conductive pillars in some alternative embodiments. The first conductive terminals 120 may be formed by a ball placement process and a reflow process.

Referring to FIG. 1C, a first chip 130 and a plurality of conductive structures 140 are formed on the first surface S1 of the first carrier 110. The first chip 130 is located in the active region A while the conductive structures 140 are located in the peripheral region R. In some embodiments, the first chip 130 is coupled to the first carrier 110 in a flip-chip manner to electrically connect with the first carrier 110. An active surface of the first chip 130 is coupled to the conductive pads 114a of the first carrier 110 through first conductive bumps 132. For example, the first conductive bumps 132 may be copper bumps and solder (not illustrated) may be applied onto surfaces of the copper bumps to couple the first conductive bumps 132 and the conductive pads 114a of the first carrier 110. Furthermore, an underfill (not illustrated) may be formed in the gap between the first chip 130 and the first carrier 110 to enhance the reliability of the attachment process. The first chip 130 is, for example, an ASIC (Application-Specific Integrated Circuit). In some embodiments, the first chip 130 may be used to perform logic applications. However, it construes no limitation in the invention. Other suitable active devices may also be utilized as the first chip 130.

The conductive structures 140 surround the first chip 130. In some embodiments, the conductive structures 140 are disposed to correspond to the conductive pads 114b. The conductive structures 140 may be electrically connected to the first circuit layer 114 of the first carrier 110. A material of the conductive structures 140 includes copper, tin, gold, nickel, solder, or other conductive materials. In addition, each of the conductive structures 140 may be a single-layered structure or a multi-layered structure. In some embodiments, each of the conductive structures 140 may be a single-layered structure formed by copper, gold, nickel, or solder. In some alternative embodiments, each of the conductive structures 140 may be a multi-layered structure formed by copper-solder, copper-nickel-solder, or the like.

In some embodiments, the conductive structures 140 are conductive balls as illustrated in FIG. 1C. The conductive balls may be formed by a ball placement process or a pick-and-place process. For example, when the conductive balls are formed by the ball placement process, a stencil (not illustrated) having openings corresponding to the conductive pads 114b is provided over the first surface S1 of the first carrier 110. Subsequently, a layer of flux is printed on the conductive pads 114b exposed by the openings of the stencil. Thereafter, conductive balls (for example, solder balls, gold balls, copper balls, nickel balls, or the like) are placed over the stencil. The conductive balls are subjected to a specific vibration frequency such that the conductive balls are dropped into the opening of the stencil. Afterwards, a reflow process may be performed to enhance the attachment between the conductive balls and the conductive pads 114b, so as to form the conductive structures 140. Alternatively, when the conductive balls are formed by the pick-and-place process, a pick-and-place tool is adopted. The pick-and-place tools picks up the conductive balls (for example, solder balls, gold balls, copper balls, nickel balls, or the like) and places the conductive balls onto the corresponding conductive pads 114b. Similar to that of the ball placement process, a reflow process may be performed to ensure the attachment between conductive balls and the conductive pads 114b. In some embodiments, the conductive structures 140 may form an array arranged in a dense manner on the first carrier 110, so as to achieve the fine pitch requirement in the subsequent processes.

It should be noted that the formation order of the first chip 130 and the conductive structures 140 is not particularly limited. In some embodiments, the first chip 130 may be formed prior to the conductive structures 140. In some alternative embodiments, the formation of the conductive structures 140 may precede the foil cation of the first chip 130.

Referring to FIG. 1D, a first insulation encapsulation 150 is formed on the first surface S1 of the first carrier 110 to completely encapsulate the conductive structures 140 and the first chip 130. In other words, a thickness of the first insulation encapsulation 150 is larger than a thickness of the conductive structures 140 and a thickness of the first chip 130. The first insulation encapsulation 150 may include a molding compound disposed on the first carrier 110 by a molding process. In some alternative embodiments, the first insulation encapsulation 150 may be formed by an insulating material such as epoxy or other suitable resins.

Referring to FIG. 1E, the first insulation encapsulation 150 is grinded until top surfaces of the conductive structures 140 are exposed. As illustrated in FIG. 1E, the first insulation encapsulation 150 exposes top surfaces 142a of the conductive structures 140. The top surfaces 142a of the conductive structures 140 and the top surface 152a of the first insulation encapsulation 150 are coplanar. The grinding process may be achieved by, for example, mechanical grinding, Chemical-Mechanical Polishing (CMP), etching, or other suitable methods. In some embodiments, a pitch p between centers of two adjacent conductive structures 140 ranges from 0.1 mm to 0.4 mm. That is, the top surfaces 142a of the conductive structures 140 may be considered as fine pitch traces or pads. Herein, the first package structure 100 is substantially completed.

In some embodiments, the conductive structures 140 may be grinded to yield larger area of the top surfaces 142a for easier and better electrical connection in the subsequent processes. That is, part of the conductive structures 140 is removed. In some alternative embodiments, after the top surfaces 142a of the conductive structures 140 are exposed, the first insulation encapsulation 150 and the conductive structures 140 may be further grinded to expose the top surface T of the first chip 130. As a result, the first insulation encapsulation 150 exposes the top surface T of the first chip 130. In some embodiments, the top surfaces 142a of the conductive structures 140, the top surface 152a of the first insulation encapsulation 150, and the top surface T of the first chip 130 are coplanar. Since the top surface T of the first chip 130 is exposed to the air, the heat generated by the first chip 130 during operation may be dissipated in a more efficient manner. Alternatively, in some other embodiments, after the top surface T of the first chip 130 is exposed, the grinding process is continued such that the first chip 130 is grinded. As a result, the overall thickness of the first package structure 100 may be effectively reduced. As mentioned above, since the first chip 130 is disposed by a flip-chip manner, the active surface thereof faces toward the first carrier 110. In other words, the top surface T of the first chip 130 is the non-active surface of the first chip 130. Therefore, even if part of the non-active surface is grinded/removed, the electrical property of the first chip 130 is not compromised.

It should be noted that in FIG. 1D, the thickness of the conductive structures 140 is illustrated as larger than the thickness of the first chip 130. Therefore, it is possible to expose the top surfaces 142a of the conductive structures 140 without grinding the first chip 130 (the first chip 130 is still well protected by the first insulation encapsulation 150). However, in some alternative embodiments, the thickness of the conductive structures 140 before grinding is less than or equal to the thickness of the first chip 130. In order to expose the top surface of the conductive structures 140, the first chip 130 is required to be grinded. Under this condition, part of the first chip 130 is removed such that the top surfaces 142a of the conductive structures 140, the top surface 152a of the first insulation encapsulation 150, and the top surface T of the first chip 130 are coplanar.

FIG. 1B to FIG. 1C illustrated that the first conductive terminals 120 are formed prior to the first chip 130 and the conductive structures 140. However, it construes no limitation in the invention. In some alternative embodiments, the first conductive terminals 120 are formed on the second surface S2 of the first carrier 110 after the first insulation encapsulation 150 and the conductive structures 140 are grinded (as illustrated in FIG. 1E).

Referring to FIG. 1F, an interposer 300 is formed on the first package structure 100. The interposer includes an interposer substrate 310 and a plurality of interposer conductive terminals 320. The interposer substrate 310 includes a core layer 312, a third circuit layer 314, a fourth circuit layer 316, and a plurality of conductive vias 318. The third circuit layer 314 is located on a side of the interposer substrate 310 while the fourth circuit layer 316 is located on another side of the interposer substrate 310. The third circuit layer 314 includes a plurality of conductive pads 314a and the fourth circuit layer 316 includes a plurality of conductive pads 316a. A material and a manufacturing method of the conductive pads 314a, 316a are similar to that of the conductive pads 114a, 114b, and 116a, so the detailed descriptions are omitted herein. The conductive vias 318 penetrate through the core layer 312 to electrically connect the conductive pads 314a and the conductive pads 316a. In some embodiments, a material of the conductive vias 318 may be the same or different from the material of the conductive pads 314, 316.

The interposer conductive terminals 320 are disposed on the interposer substrate 310 and are electrically connected to at least part of the conductive pads 316a. In some embodiments, the interposer conductive terminals 320 are disposed to correspond to the conductive structures 140 of the first package structure 100 to render electrical connection between the interposer 300 and the first package structure 100. In other words, the interposer conductive terminals 320 are disposed on the peripheral region R of the first package structure 100. A material and a manufacturing method of the interposer conductive terminals 320 are similar to that of the first conductive terminals 120, so the detailed descriptions are omitted herein. As mentioned above, since the top surfaces 142a of the conductive structures 140 may be considered as fine pitch traces or pads and the interposer conductive terminals 320 are disposed to correspond to the conductive structures 140, the interposer conductive terminals 320 may be arranged in a fine pitch manner as well.

Referring to FIG. 1G, a second package structure 400 is formed on the interposer 300 to obtain the POP structure 10. The second package structure 400 is electrically connected to the interposer 300. The second package structure 400 is similar to the first package structure 100, so the detailed descriptions of the material and the manufacturing method of the elements within the second package structure 400 are omitted herein. The difference between the first package structure 100 and the second package structure 400 lies in that the second package structure 400 may exclude elements similar to the conductive structures 140 of the first package structure 100. In addition, the second package structure 400 may omit the grinding process discussed earlier.

The second package structure 400 includes a second carrier 410, a second chip 430, a second insulation encapsulation 450, and a plurality of second conductive terminals 420. The second carrier 410 has a third surface S3 and a fourth surface S4 opposite to the third surface S3. The second chip 430 is disposed on the third surface S3. The second insulation encapsulation 450 is disposed on the third surface S3 and encapsulates the second chip 430. The second conductive terminals 420 are disposed on the fourth surface S4 and are electrically connected to the conductive pads 314a of the interposer 300. In some embodiments, a pitch between two adjacent second conductive terminals 420 may be different than the pitch between two adjacent interposer conductive terminals 320. In some embodiments, the pitch between two adjacent second conductive terminals 420 may be smaller than the pitch between two adjacent interposer conductive terminals 320, but it construes no limitation in the invention. In some alternative embodiments, the pitch between two adjacent second conductive terminals 420 may be greater than the pitch between two adjacent interposer conductive terminals 320.

The second carrier 410 includes a core layer 412, a fifth circuit layer 414, a sixth circuit layer 416, and a plurality of conductive vias 418. The fifth circuit layer 414 and the sixth circuit layer 416 are formed on two opposite surfaces of the core layer 412, so as to respectively constitute the third surface S3 and the fourth surface S4 of the second carrier 410. The fifth circuit layer 414 includes a plurality of conductive pads 414a and the sixth circuit layer 416 includes a plurality of conductive pads 416a. Each of the conductive vias 418 penetrates through the core layer 412 to electrically connect the conductive pads 414a and the conductive pads 416a. Some circuit layers in the second carrier 410 are omitted in the illustration presented in FIG. 1G for simplicity. However, in some alternative embodiments, other than the fifth circuit layer 414 and the sixth circuit layer 416, the second carrier 410 may also include additional circuit layers embedded in the core layer 412 based on the circuit design.

In some embodiments, the second chip 430 is coupled to the second carrier 410 in a flip-chip manner to electrically connect with the second carrier 410. An active surface of the second chip 430 is coupled to the conductive pads 414a of the second carrier 410 through second conductive bumps 432. Furthermore, an underfill (not illustrated) may be formed in the gap between the second chip 430 and the second carrier 410 to enhance the reliability of the attachment process. Other than flip chip bonding, the second chip 430 may be coupled to the second carrier 410 through wire bonding or other connecting mechanisms in some alternative embodiments.

The manufacturing method and the shape of the conductive structures 140 in the first package structure 100 allow fine pitch arrangement of the conductive traces to be achieved. In other words, the interposer 300 stacked over the first package structure 100 may include fine pitch interposer conductive terminals 320. As such, the risk of bridging between the interposer conductive terminals 320 presented in the laser-drilling type manufacturing method is prevented and more conductive traces may be fitted within a specific area. Moreover, since the first insulation encapsulation 150 may be grinded to expose the top surface T of the first chip 130, the cooling efficiency of the first chip 130 may be further increased, thereby enhancing the performance of the POP structure 10.

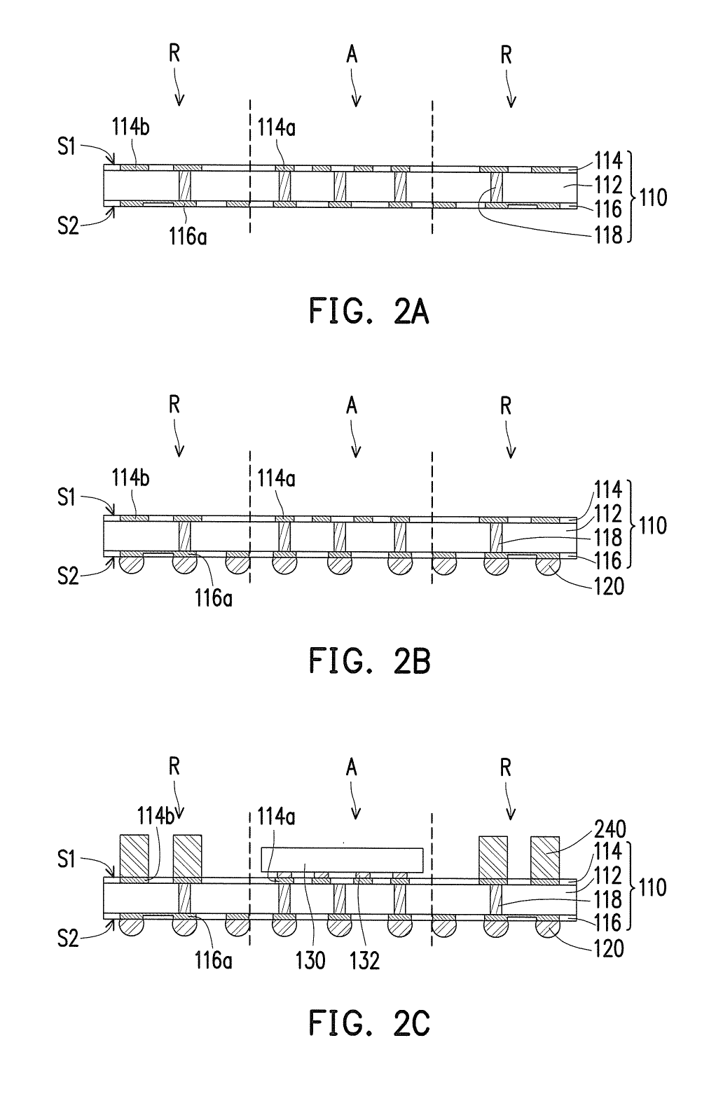

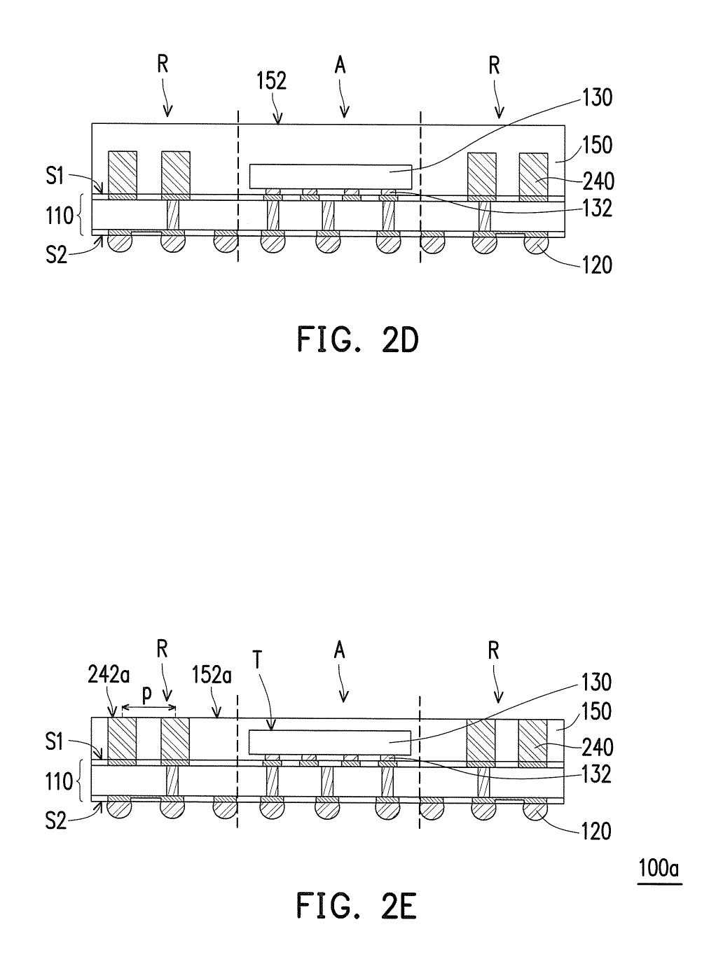

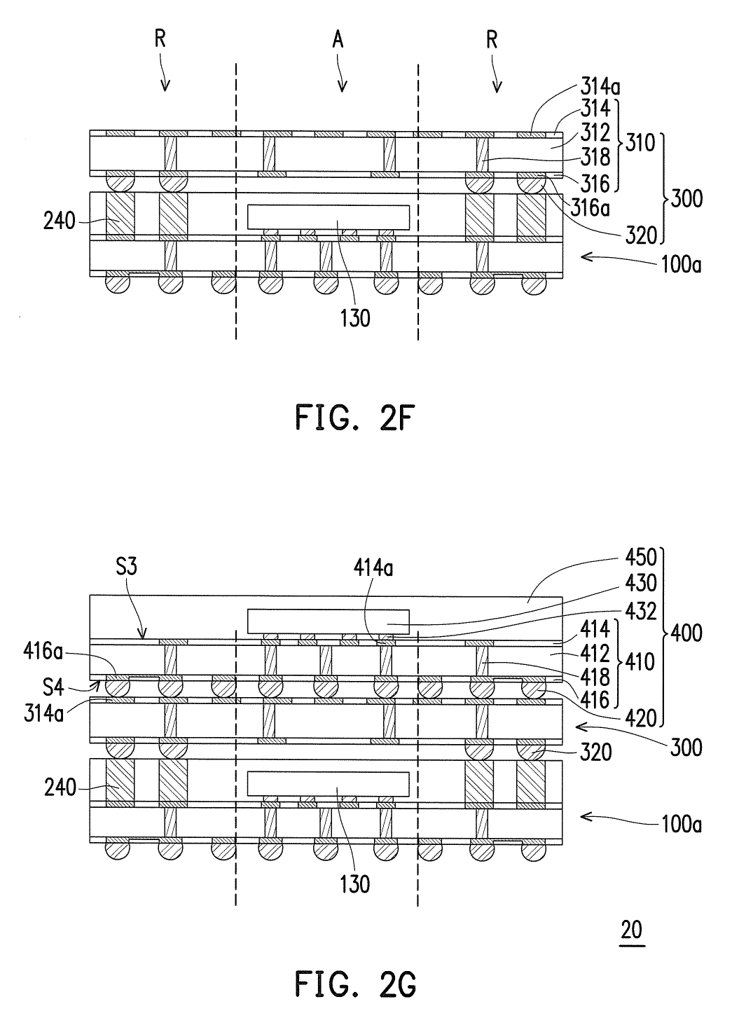

FIG. 2A to FIG. 2G are schematic cross-sectional views illustrating manufacturing method of a POP 20 structure according to another embodiment of the invention. The embodiment of FIG. 2A to FIG. 2G is similar to the embodiment of FIG. 1A to FIG. 1G, so the detailed descriptions are omitted herein. The difference between the embodiment of FIG. 2A to FIG. 2G and the embodiment of FIG. 1A to FIG. 1G lies in that in the embodiment of FIG. 2A to FIG. 2G, the conductive structures 240 are conductive pillars, as illustrated in FIG. 2C to FIG. 2E. The conductive pillars may be formed by a plating process or a pick-and-place process. For example, when the conductive pillars are formed by the plating process, the conductive pads 114b may serve as a seed layer. However, the invention is not limited thereto. In some alternative embodiments, an extra seed layer may be formed on the conductive pads 114b. A mask (not illustrated) is formed over the first carrier 110. The mask includes a plurality of openings corresponding to the seed layer (conductive pads 114b). That is, the openings expose the conductive pads 114b. Subsequently, the conductive structures 240 are filled into the openings of the mask through the plating process. The plating process is, for example, electro-plating, electroless-plating, immersion plating, or the like. Thereafter, the mask is removed to render a plurality of conducive pillars (conductive structures 240). Alternatively, when the conductive pillars are formed by the pick-and-place process, a pick-and-place tool is adopted. The pick-and-place tools picks up the conductive pillars (for example, gold pillars, copper pillars, nickel pillars, or the like) and places the conductive pillars onto the corresponding conductive pads 114b.

After the first insulation encapsulation 150 is formed on the conductive structures 240 and the first chip 130, the first insulation encapsulation 150 is grinded to expose the top surfaces 242a of the conductive pillars (conductive structures 240). In some embodiments, the conductive structures 240 may form an array arranged in a dense manner on the first carrier 110, so as to achieve the fine pitch requirement in the subsequent processes. Similar to that of the embodiment of FIG. 1A to FIG. 1G, the conductive pillars (conductive structures 240) and the first insulation encapsulation 150 may be further grinded to expose the top surface T of the first chip 130, thereby enhancing the heat dissipation efficiency of the first package structure 100a.

The manufacturing method and the shape of the conductive structures 240 in the first package structure 100a allow fine pitch arrangement of the conductive traces to be achieved. In other words, the interposer 300 stacked over the first package structure 100a may include fine pitch interposer conductive terminals 320. As such, the risk of bridging between the interposer conductive terminals 320 presented in the laser-drilling type manufacturing method is prevented and more conductive traces may be fitted within a specific area. Moreover, since the first insulation encapsulation 150 may be grinded to expose the top surface T of the first chip 130, the cooling efficiency of the first chip 130 may be further increased, thereby enhancing the performance of the POP structure 20.

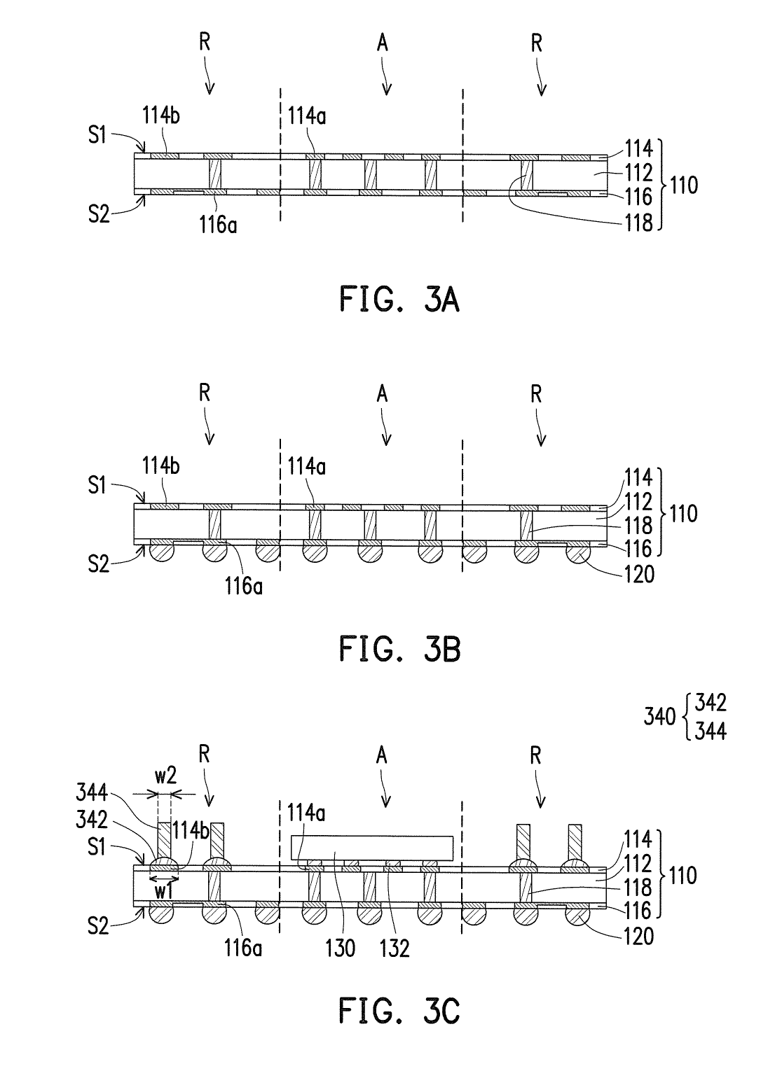

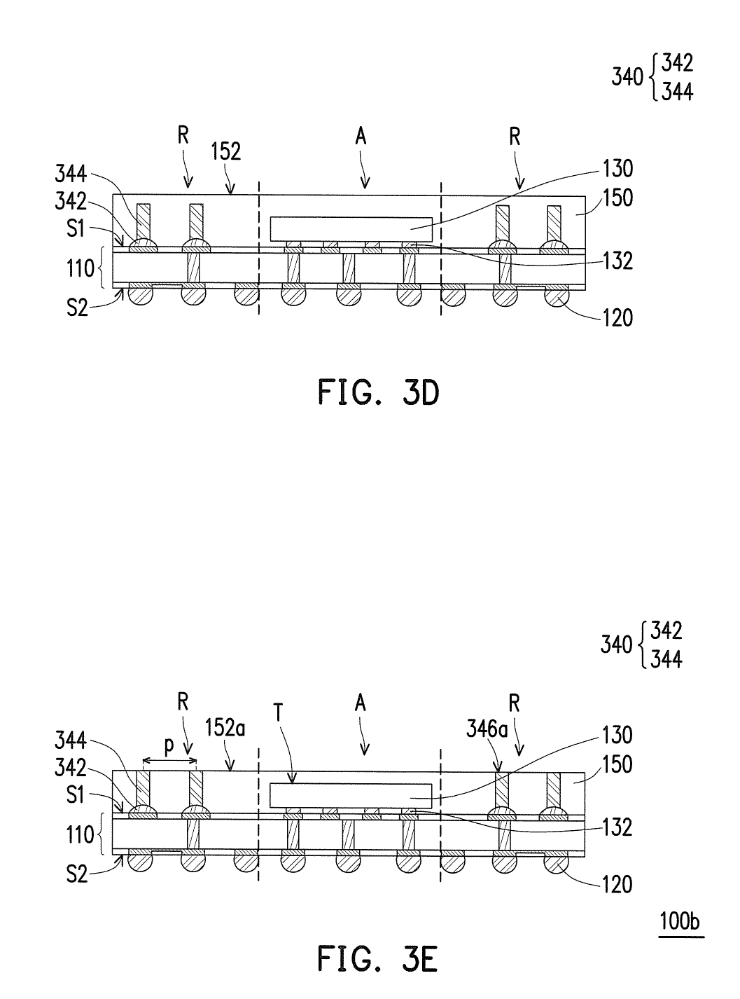

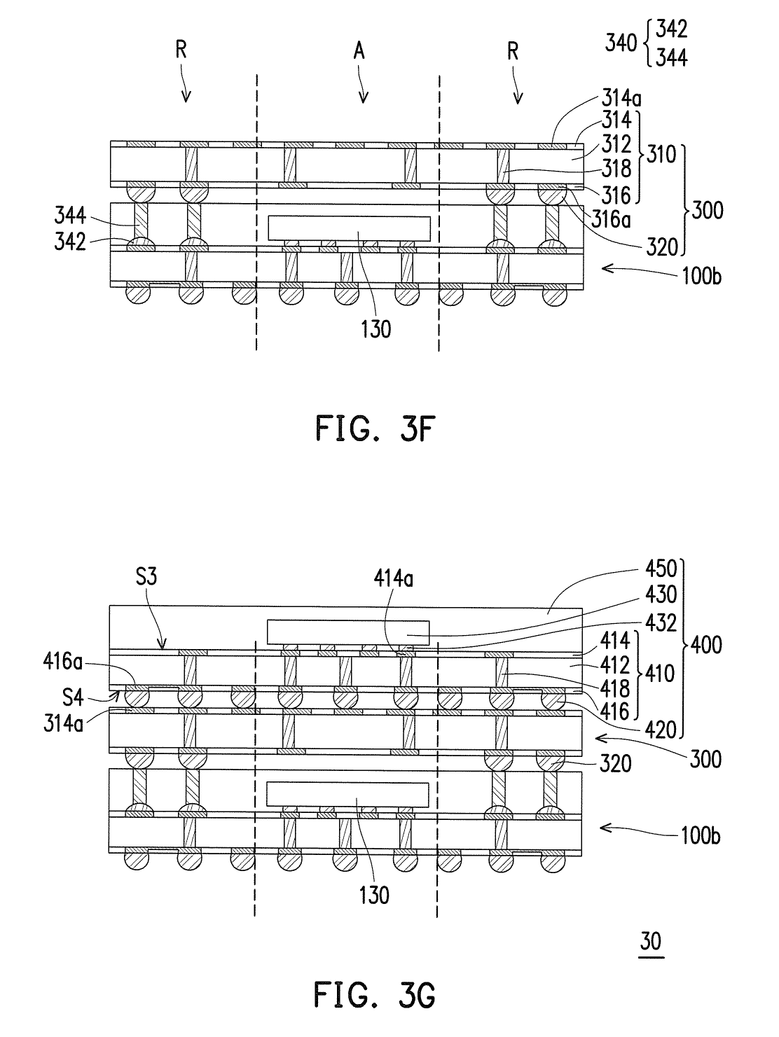

FIG. 3A to FIG. 3G are schematic cross-sectional views illustrating manufacturing method of a POP structure 30 according to yet another embodiment of the invention. The embodiment of FIG. 3A to FIG. 3G is similar to the embodiment of FIG. 1A to FIG. 1G, so the detailed descriptions are omitted herein. The difference between the embodiment of FIG. 3A to FIG. 3G and the embodiment of FIG. 1A to FIG. 1G lies in that in the embodiment of FIG. 3A to FIG. 3G, the conductive structures 340 are formed through a wire bonding process. Therefore, each of the conductive structures 340 includes a first portion 342 and a second portion 344, as illustrated in FIG. 3C. A plurality of stud bumps (first portion 342) are formed on the first S1 of the first carrier 110. The stud bumps may be formed to correspond to the conductive pads 114b of the first carrier 110. Subsequently, a plurality of bonding wires (second portion 344) are formed on the stud bumps through the wire bonding process. The second portion 344 is on the first portion 342 and a width w1 of the first portion 342 is larger than a width w2 of the second portion 344. It should be noted that the wire bonding process is conventionally known so the detailed descriptions thereof are omitted herein.

Referring to FIG. 3D to FIG. 3E, after the first insulation encapsulation 150 is formed on the conductive structures 340 and the first chip 130, the first insulation encapsulation 150 is grinded to expose the top surfaces 346a of the bonding wires (second portion 344). In some embodiments, the conductive structures 340 may form an array arranged in a dense manner on the first carrier 110, so as to achieve the fine pitch requirement in the subsequent processes. Since bonding wires are very thin, the fine pitch arrange may be further ensured. Similar to that of the embodiment of FIG. 1A to FIG. 1G, the bonding wires (second portion 344 of the conductive structures 240) and the first insulation encapsulation 150 may be further grinded to expose the top surface T of the first chip 130, thereby enhancing the heat dissipation efficiency of the first package structure 100b.

The manufacturing method and the shape of the conductive structures 340 in the first package structure 100b allow fine pitch arrangement of the conductive traces to be achieved. In other words, the interposer 300 stacked over the first package structure 100b may include fine pitch interposer conductive terminals 320. As such, the risk of bridging between the interposer conductive terminals 320 presented in the laser-drilling type manufacturing method is prevented and more conductive traces may be fitted within a specific area. Moreover, since the first insulation encapsulation 150 may be grinded to expose the top surface T of the first chip 130, the cooling efficiency of the first chip 130 may be further increased, thereby enhancing the performance of the POP structure 30.

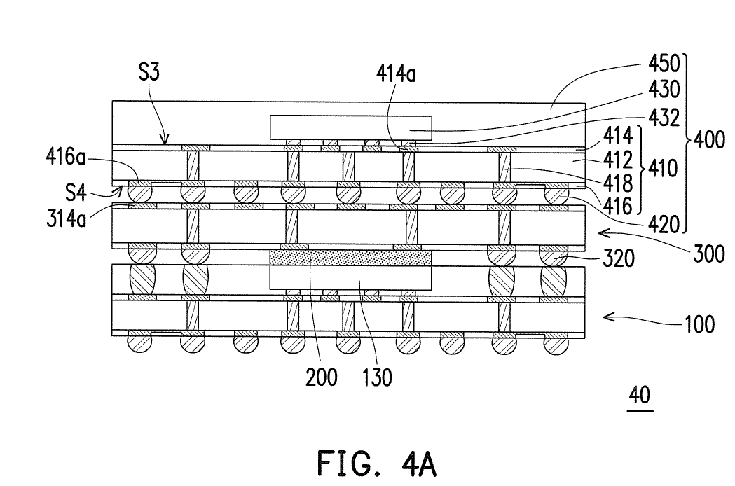

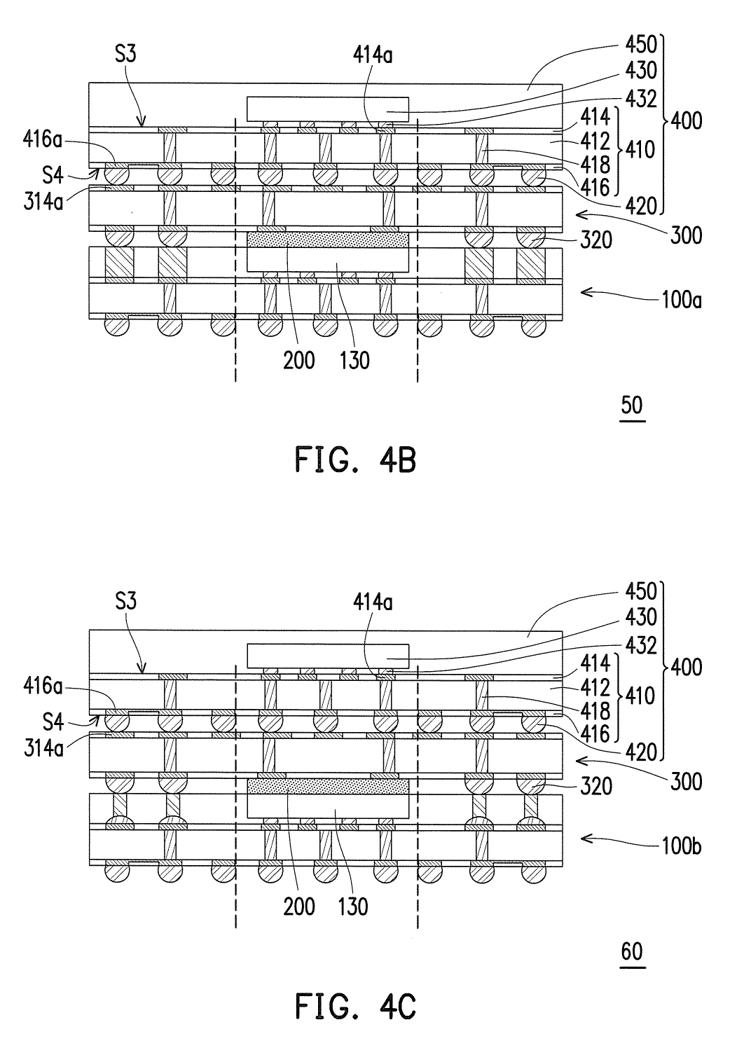

FIG. 4A to FIG. 4C are schematic cross-sectional views illustrating POP structures 40, 50, and 60 according to other embodiments of the invention. Referring to FIG. 4A, the POP structure 40 is similar to the POP structure 10 illustrated in FIG. 1G except that the POP structure 40 further includes a thermal conductive layer 200 sandwiched between the first package structure 100 and the interposer 300. Similarly, POP structure 50 of FIG. 4B is similar to POP structure 20 of FIG. 2G with the addition of the thermal conductive layer 200 while the POP structure 60 of FIG. 4C is similar to the POP structure 30 of FIG. 3G with the addition of the thermal conductive layer 200. Referring to FIG. 4A to FIG. 4C, the them al conductive layer 200 is surrounded by the interposer conductive terminals 320. In some embodiments, the thermal conductive layer 200 includes a binder and conductive powder dispersed within the binder. The binder may be made of epoxy resin, alkyd resin, acrylic resin, polyurethane resin, phenolic resin, vinyl chloride-vinyl acetate copolymer resin, or a combination thereof. On the other hand, examples of the conductive powder include metal, diamond, a combination thereof, or other suitable materials with high heat transfer coefficient. In some embodiments, the thermal conductive layer 200 may be formed by methods such as spin coating, inkjet printing, or photolithography and etching.

In some embodiments, a height H1 of the interposer conductive terminals 320 is the same as a height H2 of the thermal conductive layer 200 such that the thermal conductive layer 200 is directly in contact with the first chip 130 and the interposer 300. For example, in some embodiments, the thermal conductive layer 200 is directly in contact with the first chip 130 and the conductive pads 316a of the interposer 300, so the heat generated from the first chip 130 during operation may be transferred to the air or other dissipating structures through the conductive pads 316a, thereby further enhancing the heat dissipation efficiency. Moreover, the stress applied onto the interposer conductive terminals 320 during the subsequent reliability tests may be shared by the thermal conductive layer 200, so the issue of cracking may be eliminated.

Based on the above, the manufacturing method and the shape of the conductive structures in the first package structure allow fine pitch arrangement of the conductive traces to be achieved. In other words, the interposer stacked over the first package structure may include fine pitch interposer conductive terminals. As such, the risk of bridging between the interposer conductive terminals presented in the laser-drilling type manufacturing method is prevented and more conductive traces may be fitted within a specific area. Moreover, since the first insulation encapsulation may be grinded to expose the top surface of the first chip, the cooling efficiency of the first chip may be further increased, thereby enhancing the performance of the POP structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package-On-package (POP) structure, comprising:
a first package structure, comprising:
a first carrier having a first surface and a second surface opposite to the first surface;
a first chip disposed on the first surface of the first carrier;
a plurality of conductive structures disposed on the first surface of the first carrier; and
a first insulation encapsulation formed on the first surface of the first carrier, wherein the first insulation encapsulation encapsulates the conductive structures and the first chip, top surfaces of the conductive structures are exposed through the first insulation encapsulation and are coplanar;
an interposer disposed on and electrically connected to the first package structure; and
a second package structure disposed on and electrically connected to the interposer.

2. The POP structure according to claim 1, further comprising a plurality of first conductive terminals disposed on the second surface of the first carrier.

3. The POP structure according to claim 1, wherein the interposer comprises:
an interposer substrate; and
a plurality of interposer conductive terminals disposed on the interposer substrate, wherein each of the interposer conductive terminals is electrically connected to a corresponding conductive structure of the first package structure.

4. The POP structure according to claim 3, further comprising a thermal conductive layer disposed between the interposer and the first package structure.

5. The POP structure according to claim 4, wherein the thermal conductive layer is disposed above the first chip.

6. The POP structure according to claim 3, wherein the second package structure comprises:
a second carrier having a third surface and a fourth surface opposite to the third surface;
a second chip disposed on the third surface of the second carrier;
a second insulation encapsulation disposed on the third surface of the second carrier and encapsulates the second chip; and
a plurality of second conductive terminals disposed on the fourth surface of the second carrier, wherein the second conductive terminals are electrically connected to the interposer.

7. The POP structure according to claim 1, wherein the conductive structures are conductive pillars or conductive balls.

8. The POP structure according to claim 1, wherein each of the conductive structures comprises a first portion and a second portion, the second portion is disposed on the first portion, and a width of the first portion is greater than a width of the second portion.

9. The POP structure according to claim 1, wherein the first insulation encapsulation further exposes a top surface of the first chip, the top surface of the first chip being coplanar to the first insulation encapsulation.

10. The POP structure according to claim 6, wherein a pitch between two adjacent interposer conductive terminals is different from a pitch between two adjacent second conductive terminals.

11. A manufacturing method of a package-On-package (POP) structure, comprising:
forming a first package structure, comprising:
providing a first carrier having a first surface and a second surface opposite to the first surface;
forming a plurality of conductive structures on the first surface of the first carrier;
forming a first chip on the first surface of the first carrier;
forming a first insulation encapsulation on the first surface of the first carrier to encapsulate the conductive structures and the first chip; and
grinding the first insulation encapsulation until top surfaces of the conductive structures are exposed;
forming an interposer on the first package structure, wherein the interposer is electrically connected to the first package structure; and
forming a second package structure on the interposer, wherein the second package structure is electrically connected to the interposer.

12. The method according to claim 11, further comprising forming a plurality of first conductive terminals on the second surface of the first carrier.

13. The method according to claim 11, further comprising forming a thermal conductive layer between the interposer and the first package structure.

14. The method according to claim 13, wherein the thermal conductive layer is formed above the first chip.

15. The method according to claim 11, wherein the step of forming the conductive structures comprises attaching a plurality of conductive balls on the first surface of the first carrier.

16. The method according to claim 15, wherein the conductive balls are attached to the first surface of the first carrier through a ball placement process or a pick-and-place process.

17. The method according to claim 11, wherein the step of forming the conductive structures comprises attaching a plurality of conductive pillars on the first surface of the first carrier.

18. The method according to claim 17, wherein the conductive pillars are attached to the first surface of the first carrier through a plating process or a pick-and-place process.

19. The method according to claim 11, wherein the step of forming the conductive structures comprises:
forming a plurality of stud bumps on the first surface of the first carrier; and
forming a plurality of bonding wires on the corresponding stud bump through a wire bonding process.

20. The method according to claim 11, wherein the step of forming the first package structure further comprises grinding the first insulation encapsulation until a top surface of the first chip is exposed.
